(19) United States
(12) Patent Application Publication
(10) Pub. No.: US 2015/0123291 A1
(43) Pub. Date: May 7, 2015

(54) METHOD FOR MANUFACTURING A FLIP-CHIP CIRCUIT CONFIGURATION AND THE FLIP-CHIP CIRCUIT CONFIGURATION

(71) Applicant: Robert Bosch GmbH, Stuttgart (DE)

(72) Inventor: Florian Richter, Sonthofen (DE)

(21) Appl. No.: 14/532,709

(22) Filed: Nov. 4, 2014

(30) Foreign Application Priority Data
Nov. 5, 2013 (DE) 10 2013 222 433.8

(51) Int. Cl. H01L 21/66; H01L 23/48; H01L 23/00; H01L 21/77

(52) U.S. Cl. CPC H01L 22/12; H01L 21/77; H01L 23/48; H01L 24/16; H01L 24/81; H01L 24/48; H01L 24/85; H01L 2924/01079
USPC 257/778; 438/108; 438/15

(57) ABSTRACT

A method for manufacturing a flip-chip circuit configuration, comprising: providing a circuit carrier having a first surface and a monolithic semiconductor component having a second surface; ascertaining a height profile of the first surface of the circuit carrier; applying a first contact unit to the first surface and applying a second contact unit assigned to the first contact unit to the second surface, first contact height of the first contact unit and/or second contact height of the second contact unit being selected as a function of the ascertained height profile; and applying the semiconductor component to the circuit carrier and forming electrical connections between the first and second contact unit, by applying the second contact unit to the first contact unit and pressing the semiconductor component to the circuit carrier with deformation of the first and/or second contact unit.

### BACKGROUND OF THE INVENTION

1. Field of the Invention

The present invention relates to a method for manufacturing a flip-chip circuit configuration and a corresponding flip-chip circuit configuration.

2. Description of the Related Art

In flip-chip assembly techniques, a monolithic semiconductor component (chip, die) is mounted and contacted with its active contacting side directly on a circuit carrier, for example, a substrate or a circuit board. Contacting surfaces of the semiconductor component are contacted with printed conductors of the circuit carrier, for example, without connecting wires (wire bonds). This makes it possible to achieve a low demand for surface area.

Stud bumps made of gold, for example, are applied to the contacting surfaces of the semiconductor component using a bonding method, for example, ball-wedge bonding in particular, and are subsequently applied to the printed conductors of the circuit carrier. The semiconductor component is then pressed onto the circuit carrier, deforming the printed conductors in particular, to form electrical connections. In flip-chip methods, using nonconductive adhesive (NCA), adhesive is introduced between the chip and the circuit carrier prior to pressing.

In the case of an uneven surface of the circuit carrier in particular, which is transferred to the contact surfaces of the printed conductors, unreliable electrical contacts may occur during pressing of the stud bumps since locally different pressing forces are in effect due to the unevenness. Furthermore, individual protruding regions may result in damage or mechanical stresses.

### BRIEF SUMMARY OF THE INVENTION

According to the present invention, a height profile of the first surface of the circuit carrier is ascertained, and first contact heights of first contact means, such as, for example, printed conductors and/or second contact heights of the second contact means, such as stud bumps, for example, are selected as a function of the height profile ascertained. In particular the first contact means having a different first contact height and different amounts of material may be selected and/or the second contact means having a different second contact height and different amounts of material may be selected to compensate for the height profile ascertained.

A few advantages are achieved according to the present invention:

Contact defects due to contact means not coming in contact when the distance or stresses are too great due to protruding contact means when the distance is too small may be largely or entirely prevented. The pressing force may thus be adjusted uniformly and evenly for the contact means.

The additional effort due to the height measurement is relatively minor here. It is thus recognized according to the present invention that the monolithic semiconductor component generally has a very flat second surface and therefore only a measurement of the first surface of the circuit carrier is necessary, in particular in the case of injection molded or molded circuit carriers. Furthermore, the height measurement may be limited to a lateral region, in which the contact means are to be applied, i.e., essentially the surface of the chip to be mounted.

This yields the advantage of a low effort since the height of only one surface is to be measured and then only a relatively small region is to be measured, in particular in a tactile or noncontact method.

In a tactile measuring method, the surface of the circuit carrier is scanned by contact, for example, by using a tip, and height information for each point scanned is saved. White light interferometry, in which the surface of the component is irradiated with white light in the relevant surface region, and the reflecting white light radiation is superimposed on radiation not reflected by the surface, and a height of the surface in the surface region is ascertained from the resulting interference pattern; for example, this method may be used as a noncontact method.

This achieves the advantage that a locally resolved height profile of the corresponding surface regions may be created using a relatively simple sensor system and thus unevenness is easily detectable.

In addition, there is the advantage of a high homogeneity or uniformity of the pressing force on the various contact means. Due to the adaptation of the contact height of the first and/or second contact means to the surface properties, it is possible to achieve the result that, within a manufacturing-related tolerance, a first surface profile formed by the first contact means and a second surface profile formed by the second contact means have essentially the same shape so that when these contact means are pressed together, a pressing force thereby created acts on each contact means uniformly. It is thus recognized according to the present invention that the flip-chip method may be expanded by a tolerance equalization so that largely homogeneous electrical connections may be advantageously established. The differences in height may result from an intentional change in the surface of the respective component or may be unintentional, e.g., due to defects during manufacturing.

After the height profile has been determined, a contact height of the first and/or second contact means to be applied is determined as a function thereof. A total height is preferably formed as the sum of the first and second contact heights, which is different at the different contact points and represents the height profile.

The amount of material of the first and/or second contact means may thus be increased at points of the height profile at a greater distance from the first surface to the second surface.

The first contact means having the first contact height may be applied galvanically to the circuit carrier, for example, whereby a homogeneous contact surface of the first contact means, in which only a few defects are present, may advantageously be formed.

Nuggets or gold balls, so-called stud bumps, for example, may be provided as the second contact means on the chip, which may be applied to contact points on the surface of the chip. One possibility for applying such nuggets is, for example, a ball-wedge-bonding method, in which a gold ball is formed and then bonded to the contact point, forming an electrical connection between the gold ball and the contact point.

Such a bonding method is advantageous since resolutions in the micrometer range are possible, so that the second contact heights of the second contact means may be adjusted as a function of the height profile in the micrometer range. In other words, unevenness of this order of magnitude may be thereby equalized.

In addition, it is advantageously possible to prevent stress peaks from occurring when applying the contact means to one another, so that a complete discharge takes place, for example, via one or a very few contact means due to a static charge buildup of the contact means or the components, but instead the discharge takes place uniformly over a plurality of contact means, so that damage may be prevented.

### BRIEF DESCRIPTION OF THE DRAWINGS

FIG. 1 shows a circuit configuration prior to contacting.

FIG. 2 shows the step of measuring the height.

FIG. 3 shows the height profile measured in FIG. 2, plotted in an x direction.

FIGS. 4, 5, and 6 show steps of the manufacturing method according to a first specific embodiment.

FIG. 6 shows the circuit configuration according to the first specific embodiment.

FIGS. 7 and 8 show steps of the manufacturing method according to a second specific embodiment.

FIG. 8 shows the circuit configuration according to the second specific embodiment.

### DETAILED DESCRIPTION OF THE INVENTION

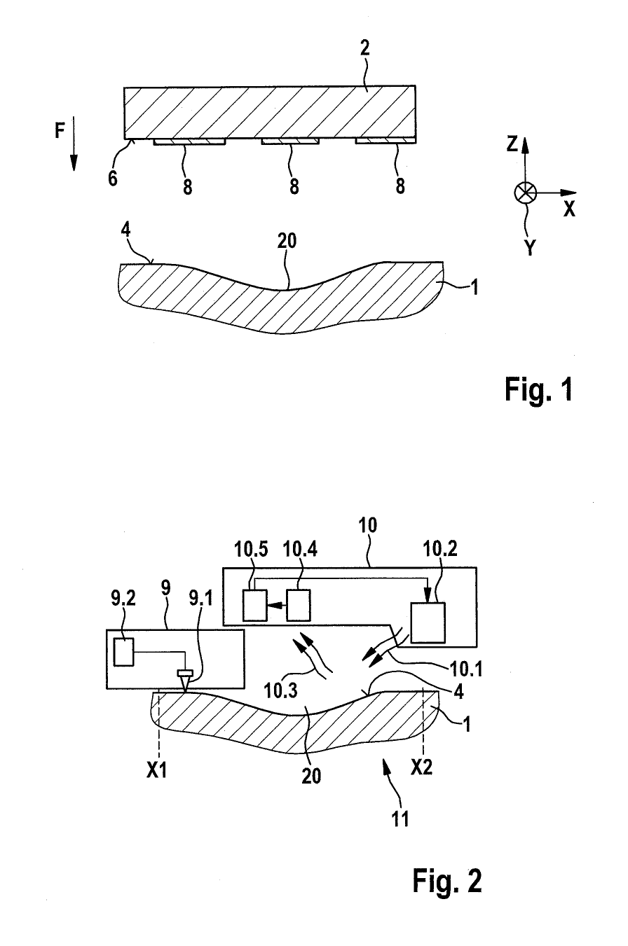

To form a flip-chip circuit configuration 3, as shown in FIGS. 6 and 8, a circuit carrier 1, for example, a circuit board, in particular an injection-molded circuit carrier 1 and a monolithic semiconductor component 2, i.e., a chip or die is initially made available according to FIG. 1. Circuit carrier 1 has a first surface 4 which may have substantial manufacturing induced tolerances in the μm range, for example, which are represented as a height relief or height profile in this view. Chip 2 has a second surface 6 which functions as a contacting side or contacting surface for a flip-chip method. Contact points 8 for contacting are formed on second surface 6 accordingly.

The drawings show essentially the same view with the extent of the surfaces in the X direction and in the mounting direction or in the pressing direction F or in the vertical Z direction; the corresponding dimensioning in the Y direction corresponds to the X direction. Circuit carrier 1 is nonconducting in a known way. Printed conductors or other contact surfaces are usually applied according to the present invention as first contact means 5 or 5.1, 5.2, 5.3.

FIG. 1 shows a recess 20 in first surface 4 as an example. Accordingly, multiple of such recesses occur in general, in particular also those having a two-dimensional extent in the X and Y directions.

Prior to applying first contact means 5 or 5.1, 5.2, 5.3, according to FIG. 2, a height profile 22 of first surface 4 of circuit carrier 1 is constructed, and a tactile measuring device 9, which scans surface 4 with the aid of a measuring head 9.1 or a tip, for example, and records the height measuring signals via a control unit 9.2 and processes them for display of a height profile 22 is used according to FIG. 2 to measure height profile 22. In addition, according to FIG. 2—in addition to or as an alternative to tactile measuring device 9—a noncontact measuring device 10 may be provided, in particular using an optical measuring method, for example, a white light method, in which optical radiation 10.1 is emitted by radiation source 10.2 onto first surface 4, and radiation 10.3 reflected by first surface 4 is subsequently analyzed, in particular based on interference with unreflected radiation of radiation source 10.2, for example, via a beam splitter, to be able to recreate the height profile of first surface 4 via a detector 10.4 from the interference pattern of the superimposed radiation with the aid of an evaluation device 10.5.

In the measuring method according to FIG. 2, the measurement may be restricted to a relevant surface region 11, for example, within limits X1 and X2, which thus essentially corresponds to or is somewhat smaller than the surface area of chip 2.

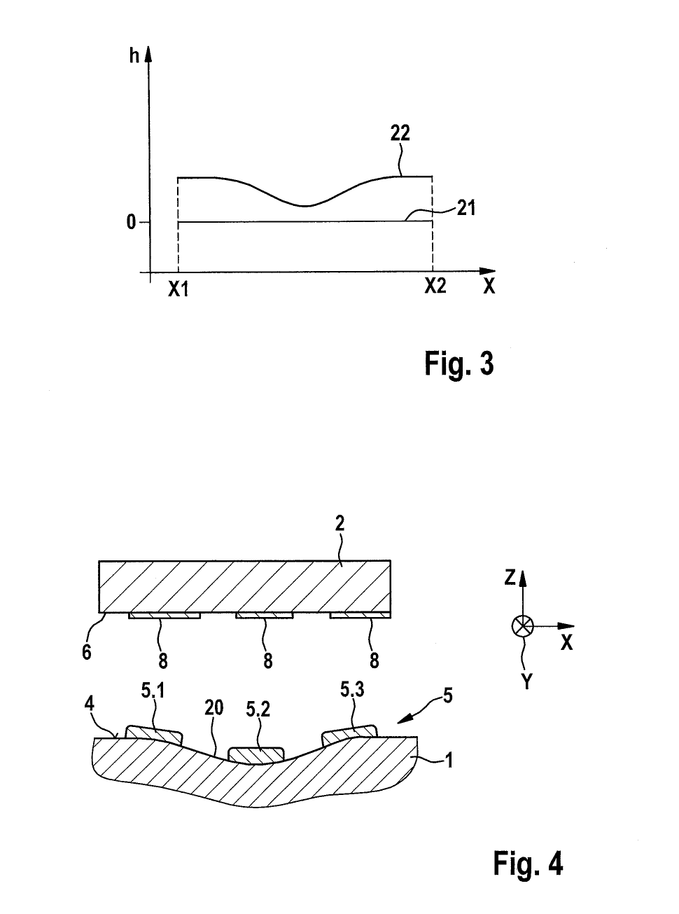

FIG. 3 shows subsequent height profile 22 which is created on the basis of the measuring signals from respective control unit 9.2 or 10.5 and is shown here for illustration as height h as a function of direction x, but in particular is to be created two-dimensionally in the x and y directions and is preferably created in relation to a reference height 21.

The heights of the first or second contact means are adjusted below according to different specific embodiments.

According to the first specific embodiment of FIGS. 4, 5 and 6, first contact means 5.1, 5.2, 5.3 having a constant first contact height 23.1=23.2=23.3 are adjusted according to FIG. 4, so that a first surface profile 26 of the first contact means corresponds essentially to surface profile 22 of FIG. 3, i.e., runs essentially in parallel to first surface 4. Second contact means 7.1, 7.2, 7.3 are applied to contact points 8 of chip 2 and adjusted using different second contact heights 24.1, 24.2, 24.3 in such a way that second contact heights 24.1, 24.2, 24.3 form a second surface profile 27, which in turn corresponds essentially to surface profile 22 ascertained according to FIG. 3.

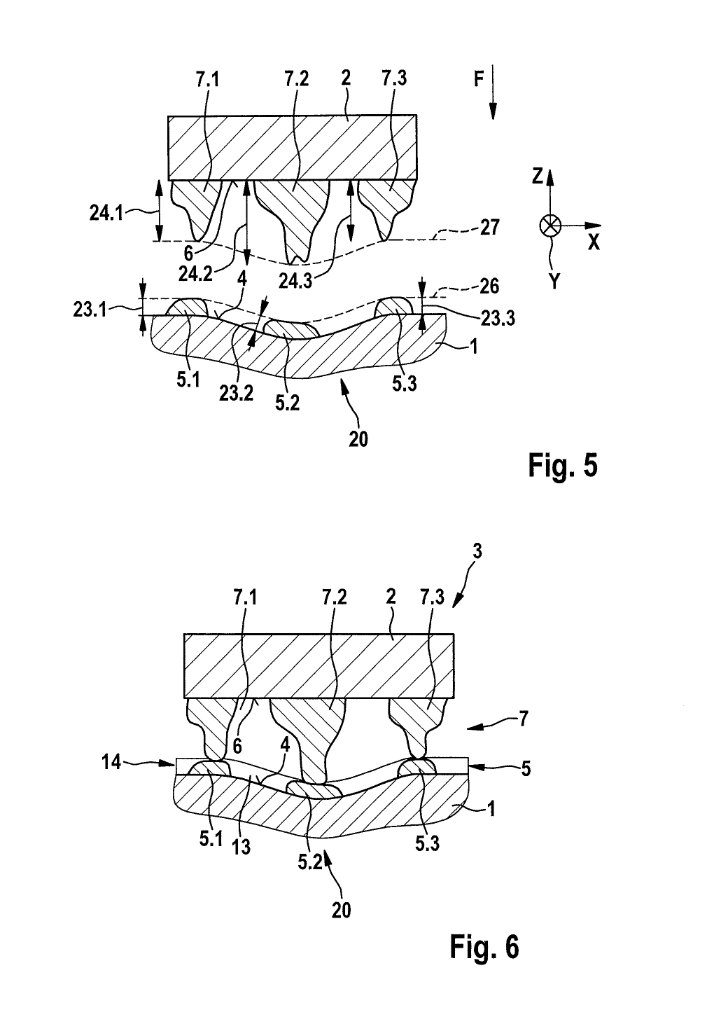

First contact means 5.1, 5.2, 5.3 may be formed galvanically according to FIG. 4 or by adhesive bonding or by application of printed conductors having a constant thickness, for example. Second contact means 7.1, 7.2, 7.3 according to FIG. 5 may be applied in particular using a ball bonding method, in which a ball wedge bonder, for example, is provided, a gold wire protruding out of its tip. The protruding end of the gold wire is guided over respective contact point 8 and then heated, so that the gold melts and forms a gold ball due to the surface tension. The gold ball is then pressed onto contact point 8 and bonded there by an ultrasonic pulse, for example, so that an electrical connection is formed between the gold ball and contact point 8. Next, the remaining wire is cut off just above the gold ball. The gold ball including the cut-off wire then forms second contact means 7.1, 7.2 or 7.3. Therefore, specific second contact means 7.1, 7.2, 7.3, which is essentially tulip-shaped, for example, and having the desired second contact height 24.1, 24.2, 24.3, may be formed.

Second contact heights 24.1, 24.2, 24.3 are adjustable in the micrometer range, for example. The amount of material of second contact means 7.1, 7.2, 7.3 is thus generally different in this specific embodiment. In this specific embodiment, the amount of material of first contact means 5.1, 5.2, 5.3 is essentially the same.

Second contact heights 24.1, 24.2, 24.3 are thus advantageously adjusted in such a way that a total height 23.1+24.1; 23.2+24.2; 23.3+24.3 (not shown in the figures for the sake of clarity), which is the result of the sum of first contact height 23.1=23.2=23.3 and of second contact heights 24.1, 24.2, 24.3, corresponds to the ascertained distance from first surface 4 to second surface 6 in the region of respective contact means 5, 5.1, 5.2, 5.3.

The mounting and contacting then take place in FIG. 6 by compacting or pressing chip 2 in joining direction F, i.e., in the Z direction here. In addition, an electrically nonconductive adhesive 13, for example, may be introduced into surface region 11, which thus secures an assembly. Adhesive 13 is extruded between the contact means and has an adhesive or bonding effect, and adhesive 13 may also cover second surface 6. In this mounting process, i.e., pressing, second contact means 7.1, 7.2, 7.3 generally undergo deformation and first contact means 5.1, 5.2, 5.3 may also deform.

Contacting also occurs essentially simultaneously in that, according to the contact step or joining step from FIG. 5 to FIG. 6, first surface profile 26 and second surface profile 27 run essentially in parallel or at a constant distance, so that unwanted discharges caused by a static charge buildup, for example, may be dissipated via a plurality of contact means and damage may be prevented. The force application is uniform via the multiple contact means during the joining operation, so that, in the embodiment according to FIG. 6, there is a uniform force application over the various contacts and first contact means 5.1, 5.2, 5.3 and second contact means 7.1, 7.2, and 7.3. The electrical connections are thus uniform and mechanical stress peaks on the external contact means in lateral directions x, y, for example, i.e., contact means 5.1, 7.1 and 5.3, 7.3 in FIG. 5, may be prevented despite the lower height.

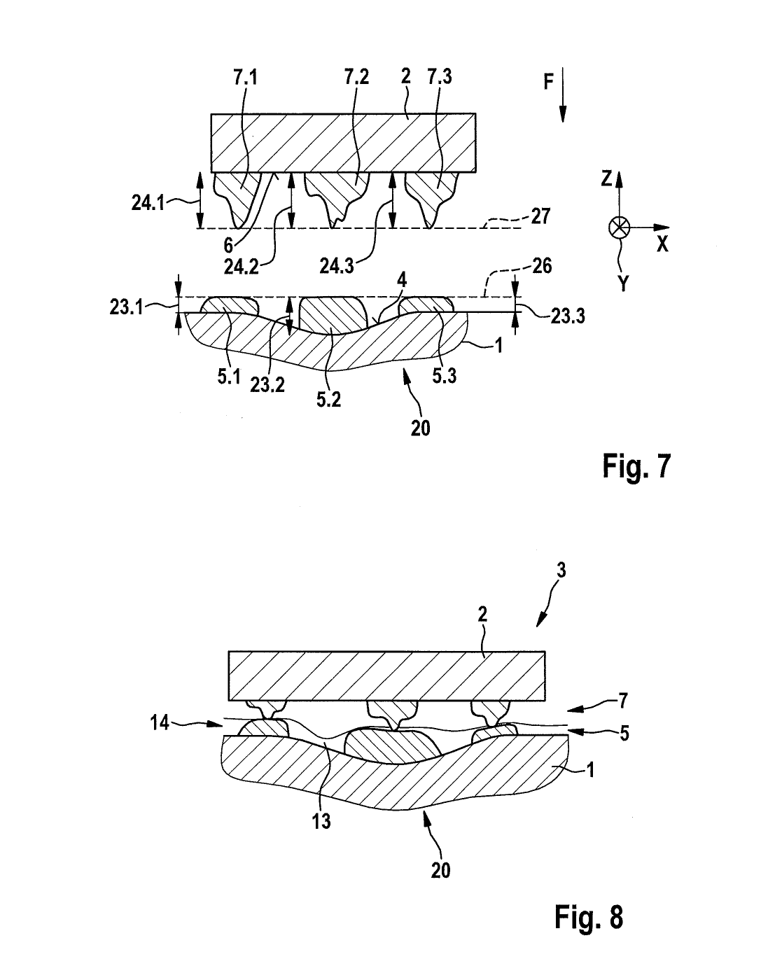

According to the second specific embodiment in FIGS. 7 and 8, first contact height 23.1, 23.2, 23.3 of first contact means 5.1, 5.2, 5.3 is adjusted differently. This may take place in particular in a galvanic deposition process.

According to FIG. 7, after ascertaining surface profile 22 of FIG. 3, essentially a first planar surface profile 26 and a second planar surface profile 27 are adjusted in that first contact means 5.1, 5.2, 5.3 equalize height profile 22 of first surface 4. Here again, there is a constant distance, i.e., a constant total height, as the sum of first and second contact heights 23.1+24.1; 23.2+24.2; 23.3+24.3 during the joining operation, so that in the joining operation according to FIG. 8, in which an electrically nonconductive adhesive 13 may in turn be applied, contact occurs essentially at the same time, and here again, the mechanical load or the force application over the various contact means is essentially constant. Therefore, both mechanical stress peaks and faulty contacting are again prevented.

In addition, mixed specific embodiments are also possible in which first contact heights 23.1, 23.2, 23.3 and also second contact heights 24.1, 24.2, 24.3 are altered.

Basically, according to the steps of FIGS. 5 and 7, the embodiment shown here may initially be measured again, and in FIG. 7 in particular, simple visual inspection for whether essentially planar surface profiles 26 and 27 are formed is possible. However, such an inspection is basically not necessary.

Adhesive 13 may also be applied to first surface 4 and/or second surface 6.

Thus, circuit configurations 3 of circuit carrier 1, monolithic chip component 2 and electrical contacts of a first contact means 5.i and a second contact means 7.i, wherein i=1, 2, 3, are made possible in FIGS. 6 and 8. The amounts of material of these contact means and contact bridges differ accordingly to calculate the ascertained height profile 22 of FIG. 3.

What is claimed is:

1. A method for manufacturing a flip-chip circuit configuration, comprising:
providing a circuit carrier having a first surface and a monolithic semiconductor component having a second surface;
ascertaining a height profile of the first surface of the circuit carrier;
applying at least one first contact element to the first surface and applying at least one second contact element assigned to the at least one first contact element to the second surface, at least one of a first contact height of the at least one first contact element and a second contact height of the at least one second contact element being selected as a function of the ascertained height profile of the first surface;
applying the semiconductor component on the circuit carrier and forming at least one electrical connection between the at least one first contact element and the at least one second contact element by applying the at least one second contact element to the at least one first contact and pressing the semiconductor component with the circuit carrier to deform at least one of the at least one first contact element and the at least one second contact element.

2. The method as recited in claim 1, wherein a total height formed by the sum of the first contact height of the at least one first contact element and of the second contact height of the at least one second contact element corresponds to an ascertained distance from the first surface to the second surface in the region of the at least one first contact element.

3. The method as recited in claim 2, wherein multiple first contact elements and multiple second contact elements are provided, and wherein at least one of (i) the amounts of material of the multiple first contact elements and (ii) the amounts of material of the multiple second contact elements are selected as a function of the ascertained height profile of the first surface.

4. The method as recited in claim 2, wherein the height profile of the first surface is ascertained only in a first surface region of the first surface in which the at least one first contact element is formed.

5. The method as recited in claim 2, wherein prior to forming the at least one electrical connection, a nonconductive adhesive is applied to the first surface and the at least one first contact element, and the adhesive cures one of during or after the pressing and formation of the at least one electrical connection.

6. The method as recited in claim 2, wherein the height profile is ascertained in at least one of a tactile and noncontact method using at least one of a first measuring device and a second measuring device.

7. The method as recited in claim 1, wherein a first surface profile formed by the at least one first contact element having the first contact height has substantially the same shape as a second surface profile formed by the at least one second contact element having the second contact height.

8. The method as recited in claim 7, wherein, when forming the electrical connections, the circuit carrier and the semiconductor component are positioned in such a way that the first surface profile extends approximately in parallel to the second surface profile.

9. The method as recited in claim 2, wherein the height profile of the first surface is determined by measuring the height of one of the first or second surface relative to a reference height.

10. A flip-chip circuit configuration, comprising:
a circuit carrier on which multiple first contact elements are provided; and
a monolithic semiconductor component having contact surfaces to which multiple second contact elements are applied, the first contact elements being contacted with the second contact elements by pressing;
wherein at least one of (i) the multiple first contact elements are of different sizes and (ii) the multiple second contact elements are of different sizes.

11. The flip-chip circuit configuration as recited in claim 10, wherein a first surface profile formed by the first contact elements extends approximately in parallel to a second surface profile formed by the second contact elements.

12. The flip-chip circuit configuration as recited in claim 11, wherein the circuit carrier is injection molded.
